(19) United States
(12) Patent Application Publication
(10) Pub. No.: US 2026/0122872 A1
(43) Pub. Date: Apr. 30, 2026

(54) COMPONENT MOUNTING MACHINE AND MAINTENANCE METHOD

(71) Applicant: FUJI CORPORATION, Chiryu (JP)

(72) Inventor: Takahiro OTSUKI, Chiryu-shi (JP)

(73) Assignee: FUJI CORPORATION, Chiryu (JP)

(21) Appl. No.: 18/835,595

(22) PCT Filed: Mar. 4, 2022
(86) PCT No.: PCT/JP2022/009525

§ 371 Date: Aug. 2, 2024

(51) Int. Cl. H05K 13/08; H05K 13/00; H05K 13/02

(52) U.S. Cl. CPC H05K 13/0895; H05K 13/0061; H05K 13/0215

(57) ABSTRACT

A component mounting machine of the present disclosure includes a board conveyance device configured to convey a board, a mounting machine main body that includes a head configured to hold a collection member and a head moving device configured to move the head, and that is configured to move the head with the head moving device, collect a component supplied from a feeder set on a feeder table, and mount the component on a board conveyed by the board conveyance device, and a guide member that is provided in the mounting machine main body, and that is configured to move between an advanced position advanced to a feeder table side and a retracted position retracted to a board conveyance device side to guide setting of the feeder on the feeder table in a state of being positioned at the advanced position.

### TECHNICAL FIELD

The present description discloses a component mounting machine and a maintenance method.

### BACKGROUND ART

Conventionally, there has been known a component mounting machine that uses a collection member held by a head to collect components from a feeder set on a feeder table and mounts the components on a board. For example, Patent Literature 1 discloses a component mounting machine having a guide member that guides the setting of a feeder on a feeder table. This guide member spans both ends of a mounting machine main body above the feeder table. Further, the guide member is fixed to the mounting machine main body.

### Patent Literature

Patent Literature 1: JP-A-2013-069880

### BRIEF SUMMARY

### Technical Problem

However, since the guide member disclosed in Patent Literature 1 is fixed to the mounting machine main body, the guide member may become an obstacle when an operator maintains the mounting machine main body.

The present disclosure has been made to solve such a problem, and a main object thereof is to facilitate maintenance of a mounting machine main body in a component mounting machine equipped with a guide member that guides the setting of a feeder on a feeder setting table.

### Solution to Problem

A component mounting machine of the present disclosure includes
a board conveyance device configured to convey a board,
a mounting machine main body that includes a head configured to hold a collection member and a head moving device configured to move the head, and that is configured to move the head with the head moving device, collect a component supplied from a feeder set on a feeder table, and mount the component on a board conveyed by the board conveyance device, and
a guide member that is provided in the mounting machine main body, and that is configured to move between an advanced position advanced to the feeder table side and a retracted position retracted to the board conveyance device side to guide setting of the feeder on the feeder table in a state of being positioned at the advanced position.

With this component mounting machine and maintenance method, maintenance of the mounting machine main body can be easily performed.

### BRIEF DESCRIPTION OF DRAWINGS

FIG. 1 is a schematic view of component mounting machine 10 with component supply unit 40 attached thereto.

FIG. 2 is a schematic view of component mounting machine 10 with component supply unit 40 removed.

FIG. 3 is a perspective view of feeder 20.

FIG. 4 is a perspective view of component supply unit 40.

FIG. 5 is a perspective view of component supply unit 40 when mounted on mounting machine main body 10a.

FIG. 6 is a perspective view of component mounting machine 10 with component supply unit 40 attached to mounting machine main body 10a.

FIG. 7 is a plan view of component mounting machine 10 when second cover member 50 is positioned at advanced position P1.

FIG. 8 is a plan view of component mounting machine 10 when second cover member 50 is positioned at retracted position P2.

FIG. 9 is a perspective view of slider lock 60.

FIG. 10 is a perspective view of detection sensor 70.

FIG. 11 is a block diagram showing the electrical connection relationship of component mounter 1.

FIG. 12 is a flowchart showing an example of a component mounting routine.

FIG. 13A is an explanatory view showing the operation of detection sensor 70.

FIG. 13B is an explanatory view showing the operation of detection sensor 70.

FIG. 13C is an explanatory view showing the operation of detection sensor 70.

FIG. 14A is an explanatory view showing the state of maintenance.

FIG. 14B is an explanatory view showing the state of maintenance.

### DESCRIPTION OF EMBODIMENTS

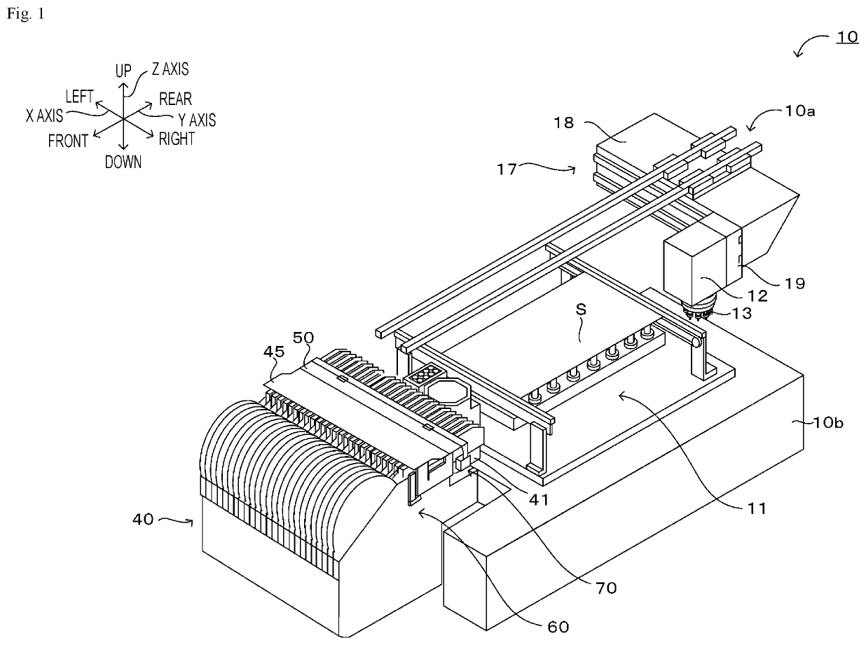

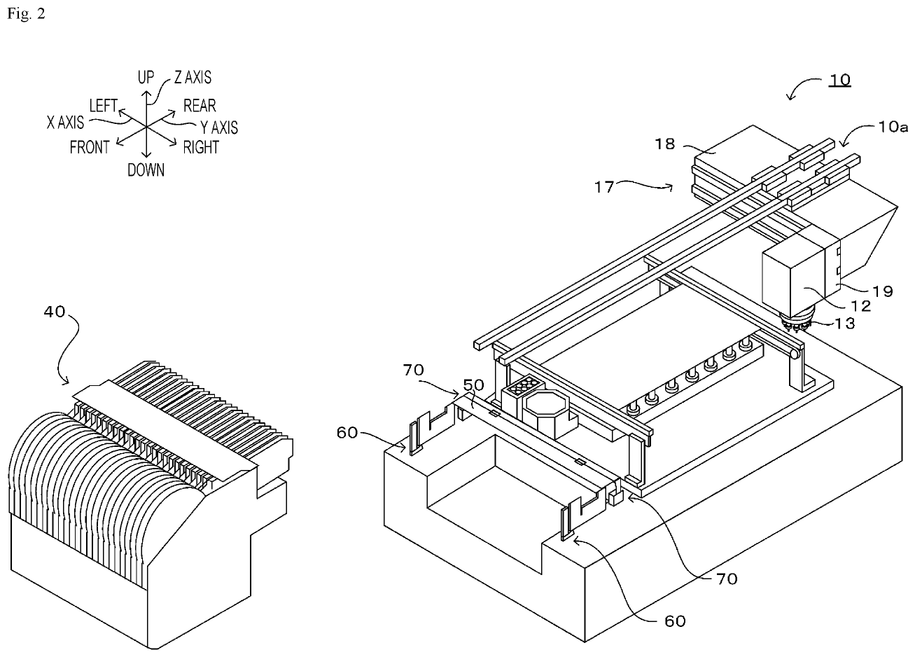

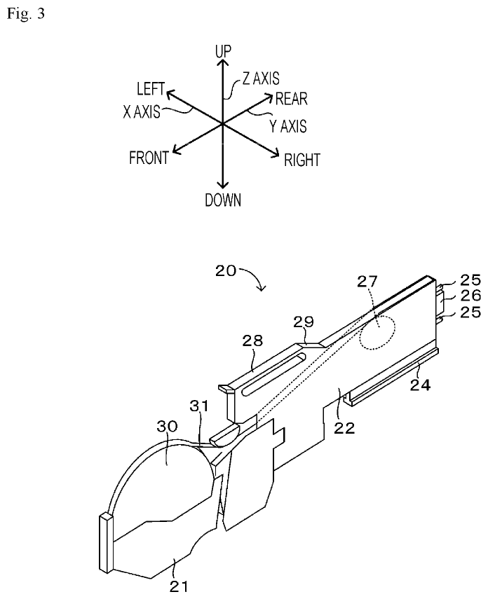

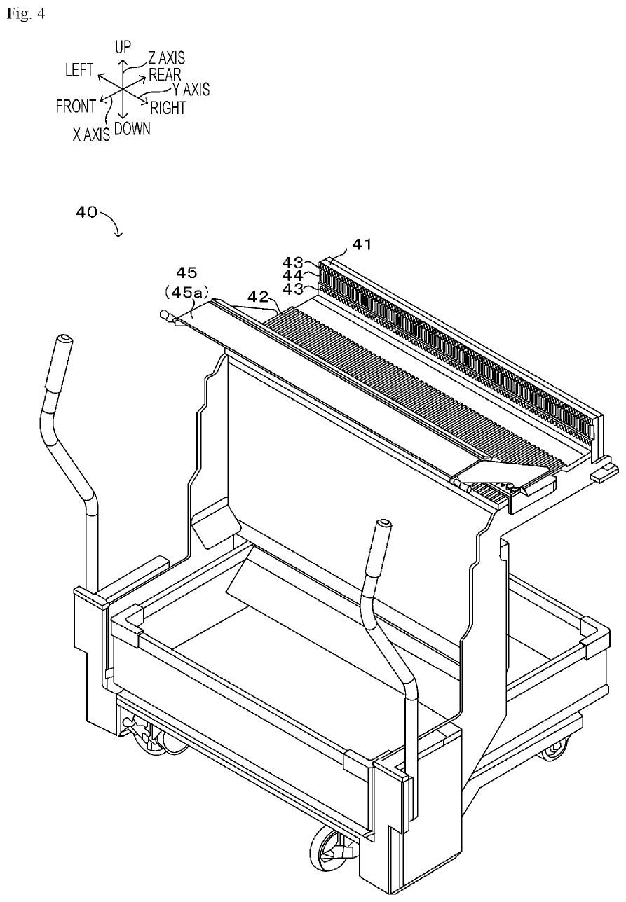

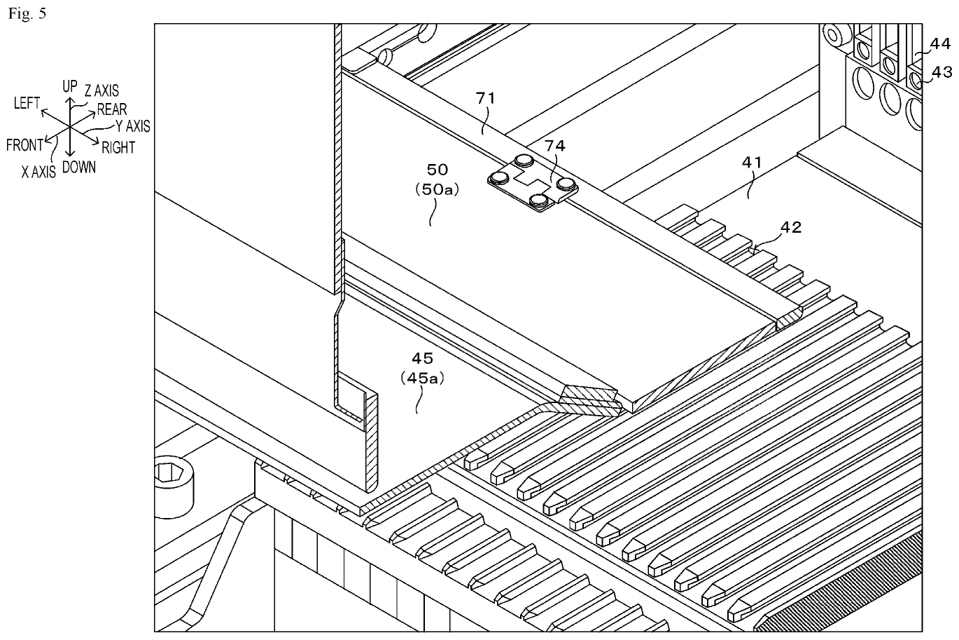

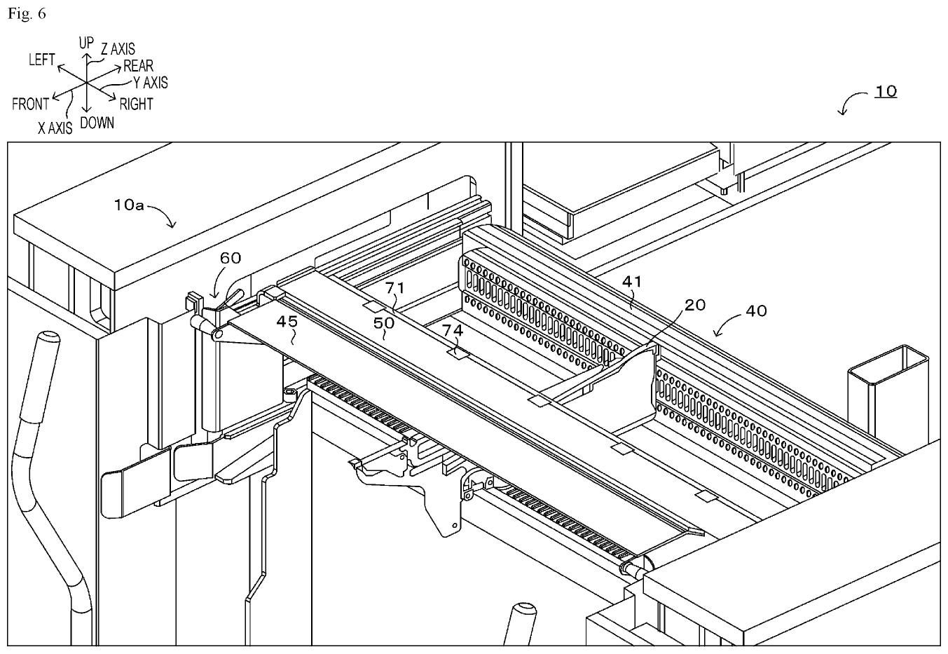

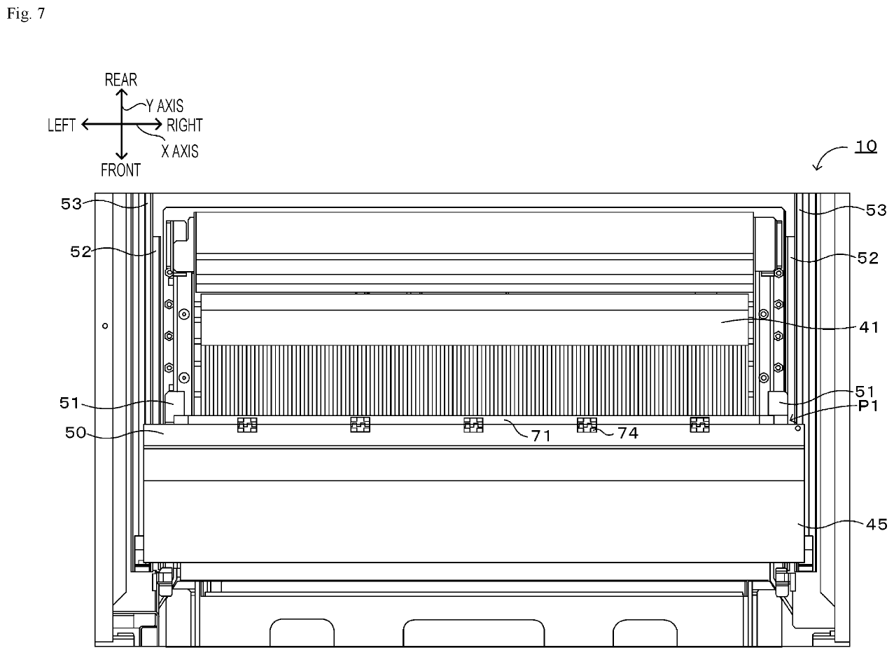

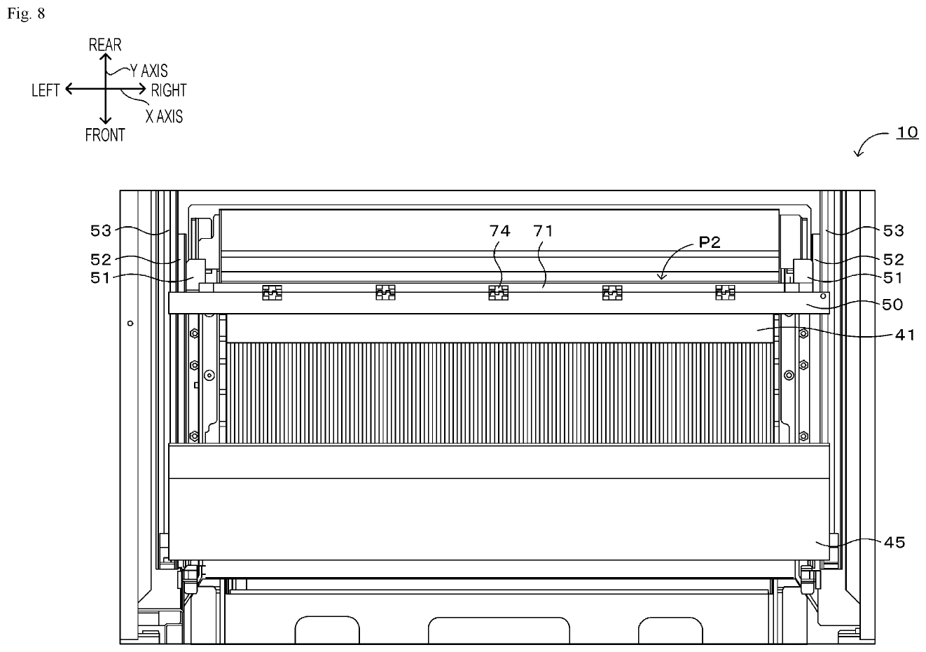

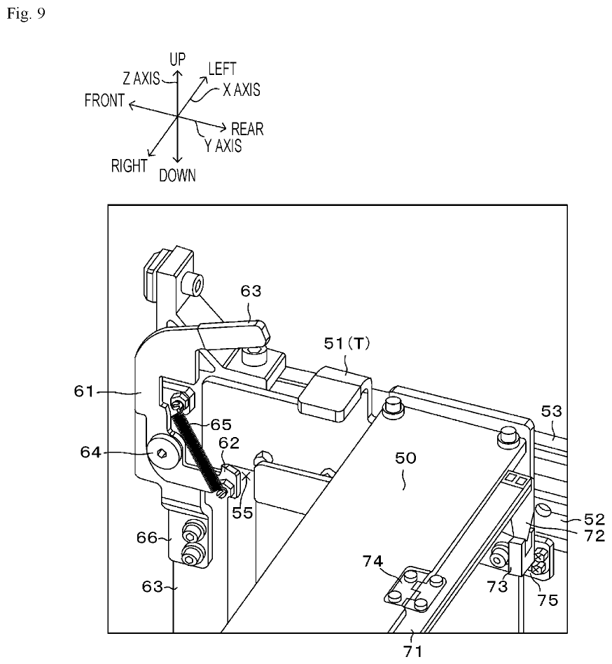

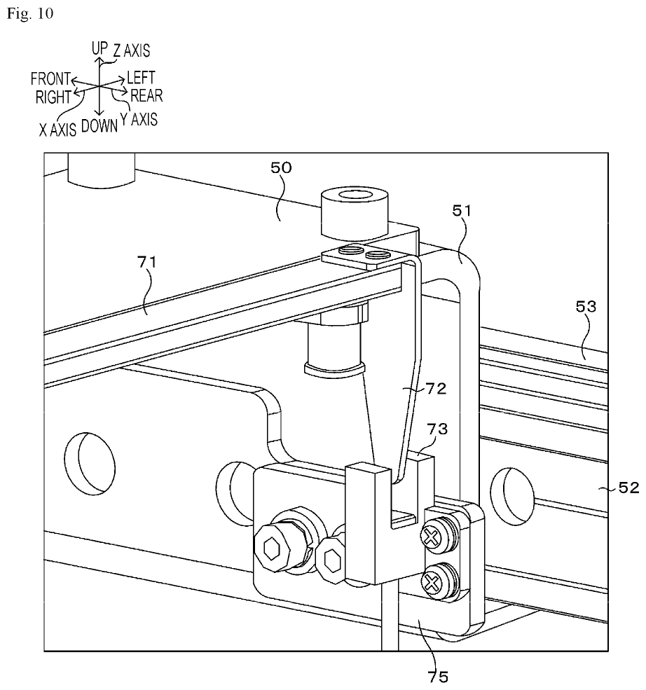

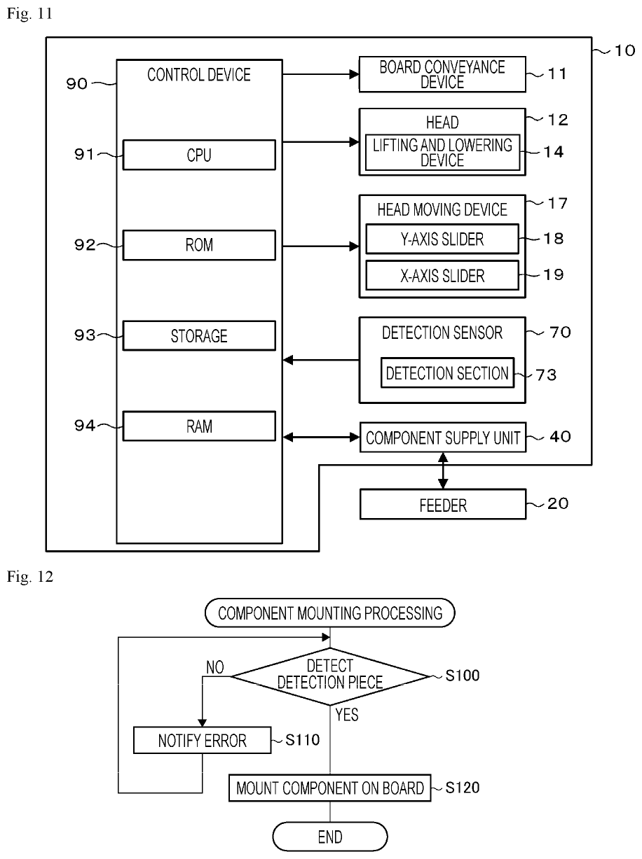

Preferred embodiments of a component mounting machine of the present disclosure will be described below with reference to the accompanying drawings. FIG. 1 is a schematic view of component mounting machine 10 with component supply unit 40 attached thereto. FIG. 2 is a schematic view of component mounting machine 10 with component supply unit 40 removed. FIG. 3 is a perspective view of feeder 20. FIG. 4 is a perspective view of component supply unit 40. FIG. 5 is a perspective view of component supply unit 40 when mounted on mounting machine main body 10a. FIG. 6 is a perspective view of component mounting machine 10 with component supply unit 40 attached to mounting machine main body 10a. FIG. 7 is a plan view of component mounting machine 10 when second cover member 50 is positioned at advanced position P1. FIG. 8 is a plan view of component mounting machine 10 when second cover member 50 is positioned at retracted position P2. FIG. 9 is a perspective view of slider lock 60. FIG. 10 is a perspective view of detection sensor 70. FIG. 11 is a block diagram showing the electrical connection relationship of component mounter 1. The left-right direction shown in FIGS. 1 to 10 is an X-axis direction, the front-rear direction shown in FIGS. 1 to 10 is a Y-axis direction, and the up-down direction shown in FIGS. 1 to 6, 9, and 10 (in FIGS. 7 and 8, the direction perpendicular to the paper surface) is a Z-axis direction.

As shown in FIGS. 1 and 2, component mounting machine 10 includes component supply unit 40 capable of holding multiple feeders 20, first cover member 45, board conveyance device 11, mounting machine main body 10a that receives components supplied from feeder 20 and mounts the components on board S, second cover member 50, and control device 90 that controls entire component mounting machine 10 (see FIG. 11).

Feeder 20 is a device that supplies components to mounting machine main body 10a. As shown in FIG. 3, feeder 20 includes a reel holding unit 21 that rotatably supports reel 30, and feeder main body 22. Tape 31 having multiple accommodation recessed portions (not shown) is wound around reel 30 in the longitudinal direction. Each accommodation recessed portion accommodates a component. A pair of upper and lower positioning pins 25 and 25 are provided on the rear end surface of feeder main body 22, and connector 26 is provided between the pair of positioning pins 25 and 25. Rail 24 having an inverted T-shaped cross-section extending in the front-rear direction is provided on the lower surface of feeder main body 22. Feeder main body 22 is provided with tape feeding mechanism 27. Tape feeding mechanism 27 pulls out tape 31 from reel 30 and conveys the same to a predetermined component supply position. As shown in FIG. 3, the upper part of feeder main body 22 has stepped surfaces 28 and 29 to form a handle of feeder 20.

Component supply unit 40 is a unit that can be attached to and detached from mounting machine main body 10a. Component supply unit 40 is a member for holding multiple feeders 20, as shown in FIGS. 1 and 2. As shown in FIGS. 4 and 5, component supply unit 40 includes feeder setting table 41.

Feeder setting table 41 is a table for setting multiple feeders 20. As shown in FIGS. 4 and 5, feeder setting table 41 has multiple slots 42 on an upper surface thereof. Slot 42 is an inverted T-shaped cross-sectional groove extending in the front-rear direction, into which rail 24 of feeder 20 is inserted. Feeder setting table 41 has a standing wall at the rear end. This standing wall is provided with connector 44 at a position corresponding to each slot 42, and positioning holes 43, 43 are provided above and below connector 44. Positioning pins 25 and 25 of feeder 20 fit into positioning holes 43 and 43 of feeder setting table 41, and connector 26 of feeder 20 is electrically connected to connector 44 of feeder setting table 41. It is communicably connected to control device 90 (see FIG. 11) of component mounting machine 10.

As shown in FIG. 4, first cover member 45 is provided on feeder setting table 41. This first cover member 45 is a member that guides feeder 20 when feeder 20 is set on feeder setting table 41, and is a cover-like member that covers stepped surfaces 28 and 29 of feeder 20 when feeder 20 is set on feeder setting table 41. When component supply unit 40 is attached to mounting machine main body 10a, the height of first cover member 45 is such that upper end surface 45a of first cover member 45 is positioned at a higher position than suction nozzle 13, which will be described later.

Board conveyance device 11 includes a pair of conveyor rails spaced apart in the Y-axis direction, and conveys board S from left to right (conveyance direction) in FIGS. 1 and 2 by driving a pair of conveyor rails.

Mounting machine main body 10a receives components supplied from feeder 20 set in component supply unit 40 and mounts the components on board S. Mounting machine main body 10a includes head 12 and head moving device 17. Mounting machine main body 10a further includes slider lock 60 and detection sensor 70.

Head 12 is a member capable of holding multiple suction nozzles 13. Head 12 includes lifting and lowering device 14 that moves suction nozzle 13 in the Z axis (up and down) direction. Suction nozzle 13 picks up (collects) components by using negative pressure supplied from a negative pressure source (not shown).

Head moving device 17 is a device that moves head 12 in the horizontal direction. Head moving device 17 includes Y-axis slider 18 that extends in the X-axis direction and is slidable in the Y-axis direction, and X-axis slider 19 that is provided to be slidable in the X-axis direction with respect to Y-axis slider 18. Head 12 is attached to the front of X-axis slider 19.

As shown in FIGS. 5 and 6, second cover member 50 is provided in mounting machine main body 10a. This second cover member 50 is a member that covers the upper part of feeder 20 when feeder 20 is set in component supply unit 40 (feeder setting table 41) attached to mounting machine main body 10a. The height of second cover member 50 is such that upper end surface 50a is positioned at a lower position than suction nozzle 13. Therefore, second cover member 50 does not interfere with suction nozzle 13 held by head 12. Second cover member 50 is connected to left and right sliders 51, 51 to span in the left and right (X axis) direction. Each slider 51 is movable in the front-rear direction (Y-axis direction) along guide rails 52 extending in the front-rear direction (Y-axis direction). Guide rails 52 are provided parallel to each other on the left and right sides of the area where feeder setting table 41 is disposed. As shown in FIG. 9, a notch (engaged part) 55 that can be engaged with hook (engaging part) 62 of slider lock 60, which will be described later, is formed in the front lower part of each slider 51. Each guide rail 52 is attached to frame member 53. Frame member 53 is fixed to base 10b (see FIGS. 1 and 2).

Since left and right sliders 51 are movable in the front-rear direction (Y-axis direction) along guide rails 52, second cover member 50 is movable between advanced position Pl as shown in FIG. 7 and retracted position P2 as shown in FIG. 8. Advanced position P1 is the position of second cover member 50 when slider 51 is positioned at predetermined position T. Further, the retracted position is a position where second cover member 50 is retracted rearward from the advanced position. When positioned at advanced position P1, second cover member 50 is close to first cover member 45 of component supply unit 40 attached to mounting machine main body 10a, and first cover member 45 and second cover member 50 guide the setting of feeder 20 and cover the upper part of set feeder 20.

Slider lock 60 is a member for positioning slider 51 at a predetermined position. Slider locks 60 are provided in front of left slider 51 and in front of right slider 51, respectively. Slider lock 60 includes lock main body 61, hook 62, and lever 63. Lock main body 61 is attached to lock attachment member 66 so that hook 62 and lever 63 can swing about shaft 64. Lock attachment member 66 is fixed to frame member 23.

Lock main body 61 is a member having a substantially C-shape when viewed in a plan view in the direction of shaft 64. Hook 62 is formed on the rear lower side of lock main body 61. Hook 62 is swingable about shaft 64 between a first position and a second position. The second position is positioned below the first position. When positioned at the first position, hook 62 engages with notch 55 provided in slider 51 to lock slider 51 and limit movement of slider 51. On the other hand, when positioned at the second position, hook 62 comes off notch 55 of slider 51 and allows slider 51 to move rearward. Hook 62 is urged upward by the elastic force of spring 65. Therefore, hook 62 is normally positioned at the first position.

Lever 63 is formed on the upper part of lock main body 61. Lever 63 is a part for operating hook 62. Lever 63 is swingable about shaft 64 between a lower position and an upper position. Lever 63 is normally positioned at an upper position by the elastic force of spring 65. At this time, hook 62 is positioned at the first position. On the other hand, when lever 63 is pushed down toward the lower position against the elastic force of spring 65, as lever 63 swings from the upper position to the lower position, hook 62 swings from the first position to the second position. When lever 63 is positioned in the lower position, hook 62 is positioned in the second position.

Detection sensor 70 is a sensor capable of detecting lifting of feeder 20 (misalignment such as rail 24 of feeder 20 not being properly inserted into slot 42) with respect to component supply unit 40 (feeder setting table 41) attached to mounting machine main body 10a, and also detecting that slider 51 is positioned at predetermined position T. As shown in FIG. 10, detection sensor 70 includes flap member 71, detected piece 72, and detection section 73.

Flap member 71 is a plate-shaped bridging member extending in the X-axis direction. As shown in FIG. 10, flap member 71 is provided at the rear of second cover member 50. Flap member 71 is rotatably attached to the rear end of second cover member 50 via hinge 74. In this way, since flap member 71 is attached to slider 51 via second cover member 50, flap member 71 is movable as slider 51 moves. When slider 51 is positioned at predetermined position T, flap member 71 is disposed at a position where flap member 71 becomes an obstacle to maintenance of mounting machine main body 10a. When component supply unit 40 with set feeder 20 is attached to mounting machine main body 10a, flap member 71 is disposed slightly above feeder 20. In addition, flap member 71 is positioned by a stopper (not shown) so that flap member 71 takes a predetermined posture (horizontal posture) with respect to second cover member 50, but flap member 71 rotates upward about hinge 74 when pushed up from below, and returns to the predetermined posture thereof due to gravity when released from being pushed up.

As shown in FIG. 7, detected pieces 72 are docks integrated with the left and right ends of the lower surface of flap member 71. Detected piece 72 moves in the front-rear direction as slider 51 moves, and is also rotatable in the up-down direction about hinge 74 as flap member 71 rotates.

Detection section 73 is an optical sensor in which a light emitting element and a light receiving element are disposed to face each other with a gap in the left-right direction. As shown in FIG. 10, detection section 73 is attached to detection section attachment member 75 provided on frame member 53 independently of slider 51. When slider 51 is positioned at predetermined position T and flap member 71 is in a predetermined posture without being pushed up from below, detected piece 72 is disposed in a gap between the light emitting element and the light receiving element of detection section 73 without contacting the light emitting element and the light receiving element. Therefore, the light emitted from the light emitting element is blocked by detected piece 72 and does not reach the light receiving element (light blocking state). At this time, the signal of detection section 73 is off. On the other hand, when flap member 71 is pushed up from below, detected piece 72 rotates upward and slips out from between the light emitting element and the light receiving element of detection section 73. Therefore, the light emitted from the light emitting element reaches the light receiving element without being blocked by detected piece 72 (light emitting state). At this time, the signal of detection section 73 is on. Further, when slider 51 moves backward from predetermined position T, since detected piece 72 slips out from the gap between the light emitting element and the light receiving element of detection section 73, the signal of detection section 73 is turned on. Detection section 73 outputs a signal to control device 90 (see FIG. 11).

As shown in FIG. 11, control device 90 is configured as a microprocessor centered around CPU 91, and includes, in addition to CPU 91, ROM 92, storage 93 (for example, an HDD or SSD), and RAM 94. Control device 90 outputs control signals to feeder 20, board conveyance device 11, head 12, and the like. Further, control device 90 receives signals from detection section 73 of detection sensor 70, feeder 20, and the like.

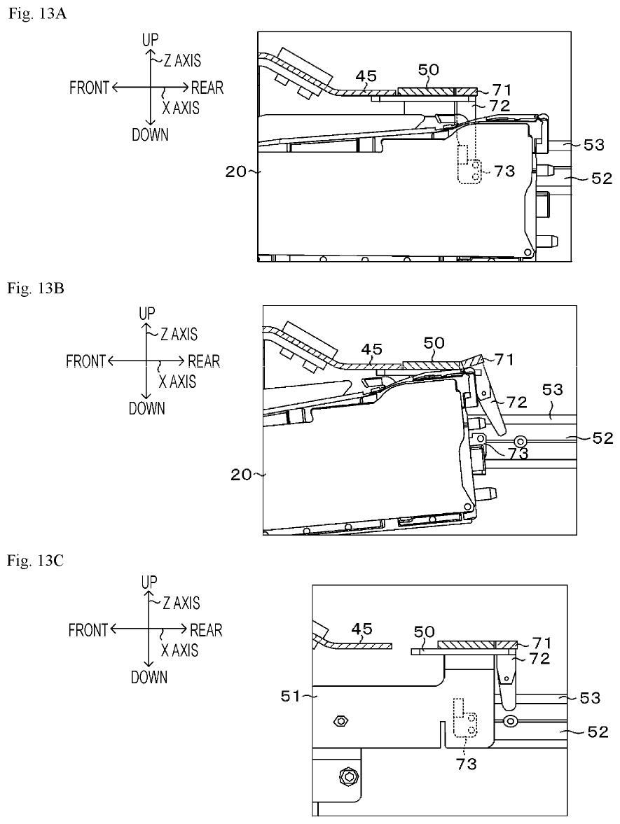

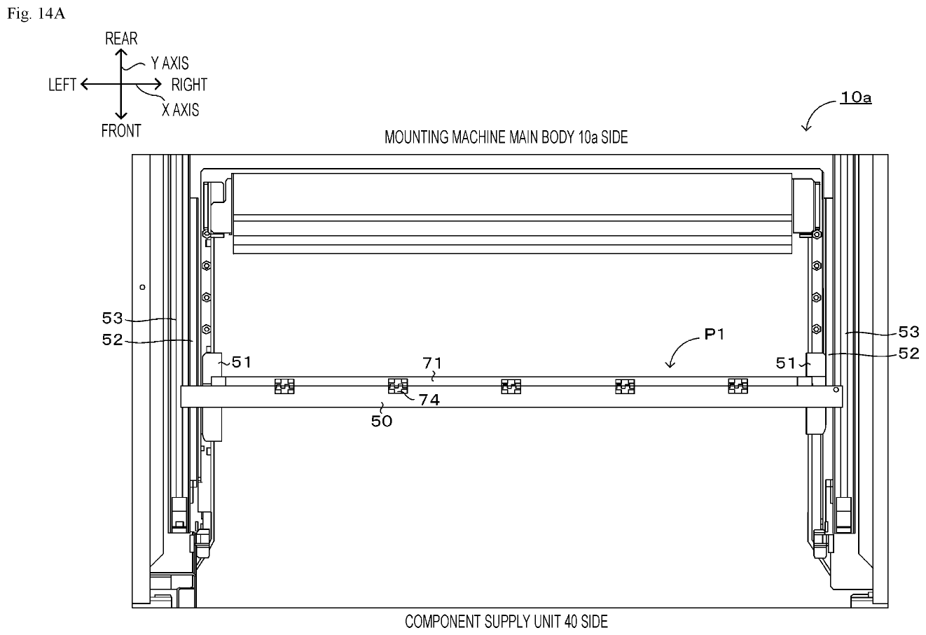

The operation of component mounting machine 10 configured in this manner will be described. First, the component mounting process executed by component mounting machine 10 will be described by using FIGS. 12 and 13. FIG. 12 is a flowchart showing an example of a component mounting processing routine. FIGS. 13A to 13C are explanatory views showing the operation of detection sensor 70. A routine for component mounting processing is stored in storage 93 and executed by CPU 91. In the present embodiment, it is assumed that component supply unit 40 is attached to mounting machine main body 10a with necessary feeders 20 set on feeder setting table 41.

When receiving a component mounting operation command, CPU 91 determines whether detection section 73 has detected detected piece 72 (S100). Specifically, CPU 91 determines whether an off signal is input from detection section 73. Here, a case where CPU 91 receives an off signal and a case where CPU 91 receives an on signal from detection section 73 will be described. First, we discuss a signal that CPU 91 receives from detection section 73 when slider 51 is positioned at a predetermined position. When feeder 20 is correctly inserted into slot 42 of feeder setting table 41, feeder 20 does not contact the lower surface of flap member 71, as shown in FIG. 13A. Therefore, feeder 20 does not push up flap member 71. At this time, flap member 71 maintains a predetermined posture with respect to second cover member 50. Therefore, detected piece 72 remains disposed between the light emitting element and the light receiving element of detection section 73. Therefore, CPU 91 receives an off signal from detection section 73 and makes an affirmative determination. On the other hand, when feeder 20 is not correctly inserted into slot 42 of feeder setting table 41, feeder 20 lifts relative to feeder setting table 41. At this time, feeder 20 contacts the lower surface of flap member 71, as shown in FIG. 13B. Therefore, feeder 20 pushes up flap member 71 from below. As a result, flap member 71 rotates upward. Therefore, as flap member 71 rotates upward, detected piece 72 also rotates upward and slips out from the gap between the light emitting element and the light receiving element of detection section 73. Therefore, CPU 91 receives an ON signal from detection section 73 and makes a negative determination. Next, we discuss a signal that CPU 91 receives from detection section 73 when slider 51 is not positioned at predetermined position T. In this case, detected piece 72 has slipped out from the gap between the light emitting element and the light receiving element of detection section 73, as shown in FIG. 13C. Therefore, in this case, CPU 91 receives an ON signal from detection section 73 and makes a negative determination.

If a negative determination is made in S100, CPU 91 notifies an operator of an error until it is confirmed that feeder 20 is normally set on feeder setting table 41 and slider 51 is positioned at predetermined position T (S110). Specifically, CPU 91 displays an error message on a display device (not shown) provided in component mounting machine 10. The operator who notices the error repositions slider 51 to predetermined position T or resets feeder 20 with respect to feeder setting table 41.

If an affirmative determination is made in S100, CPU 91 starts the processing of mounting a component on board S. This process is executed as follows. That is, CPU 91 first causes suction nozzle 13 of head 12 to pick up the component supplied from feeder 20. Specifically, CPU 91 causes Y-axis slider 18 and X-axis slider 19 to move suction nozzle 13 directly above the component suction position of a desired component. Next, CPU 91 causes lifting and lowering device 14 and a negative pressure source (not shown) to lower suction nozzle 13 and supply negative pressure to suction nozzle 13. As a result, the desired component is picked up at the tip portion of suction nozzle 13. Thereafter, CPU 91 lifts suction nozzle 13 and causes Y-axis slider 18 and X-axis slider 19 to move suction nozzle 13, which has picked up the component to the tip, above the target mounting position of board S. Then, at the predetermined position, CPU 91 lowers suction nozzle 13 and controls a positive pressure source (not shown) so that atmospheric pressure is supplied to suction nozzle 13. As a result, the components that have been picked up by suction nozzle 13 are mounted spaced apart on board S at a predetermined position. Other components to be mounted on board S are similarly mounted on board S, and when all the components have been mounted, CPU 91 causes board conveyance device 11 to send board S to the downstream side. When component mounting machine 10 is performing a mounting operation, slider 51 is locked by slider lock 60.

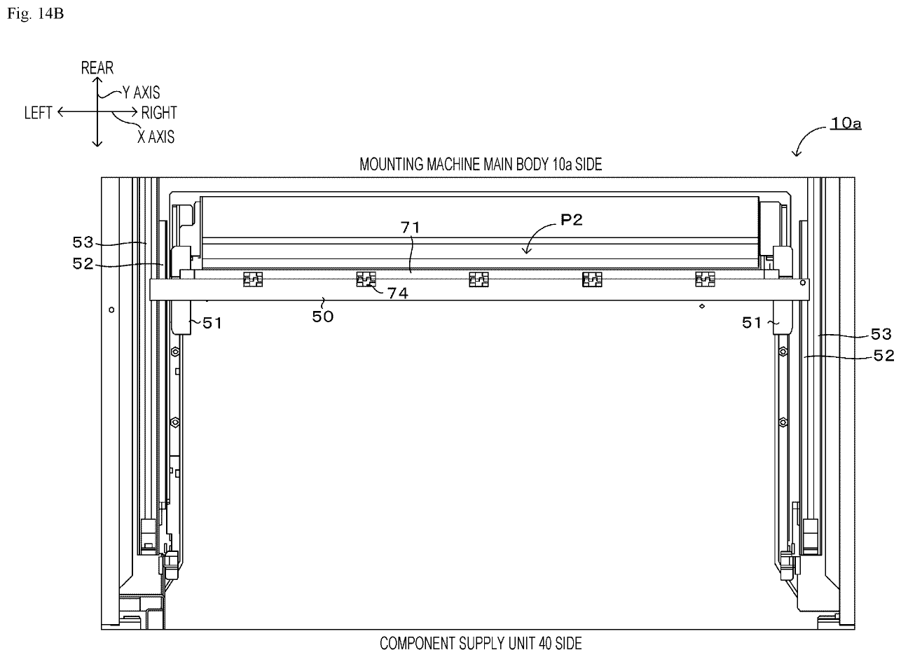

Next, maintenance of component mounting machine 10 will be described by using FIGS. 14A and 14B. FIGS. 14A and 14B are explanatory views showing the state of maintenance. Maintenance refers to, for example, work of adjusting or replacing various members provided on the upper surface of base 10b. Maintenance is performed by the operator after completing the component mounting operation. Maintenance is also performed by the operator when some abnormality occurs in component mounting machine 10.

In the maintenance, as shown in FIG. 14A, the operator first removes component supply unit 40 from mounting machine main body 10a. Next, the operator pushes down lever 63 to a lower position. As a result, hook 62 of slider lock 60 moves to the second position so that the lock of slider 51 is released. Next, as shown in FIG. 14B, the operator moves second cover member 50 and flap member 71 to the retracted position where maintenance is not disturbed. Then, the operator performs maintenance of mounting machine main body 10a. After completion of the maintenance, the operator moves slider 51 to predetermined position T. Then, hook 62 of slider lock 60 is positioned at the first position and locks slider 51 at predetermined position T.

Here, a correspondence relationship between the elements of the present embodiment and the elements of the present disclosure will be clarified. Component mounting machine 10 of the present embodiment corresponds to a component mounting machine, board conveyance device 11 corresponds to a board conveyance device, and mounting machine main body 10a corresponds to a mounting machine main body of the present disclosure. In addition, component supply unit 40 corresponds to a component supply unit, first cover member 45 corresponds to a first guide member, and second cover member 50 and flap member 71 correspond to a second guide member. Further, second cover member 50 corresponds to a member main body, and flap member 71 corresponds to a rotating body.

In component mounting machine 10 described in detail above, first cover member 45 is provided on component supply unit 40, and second cover member 50 is provided on mounting machine main body 10a, and is movable between advanced position P1 and retracted position P2. Therefore, by moving second cover member 50 to retracted position P2, second cover member 50 is no longer an obstacle to maintenance when performing maintenance on mounting machine main body 10a. Therefore, maintenance of mounting machine main body 10a can be easily performed.

In addition, component mounting machine 10 includes component supply unit 40 that includes feeder setting table 41 and is detachably attached to mounting machine main body 10a, first cover member 45 that is provided on component supply unit 40 and guides the setting of feeder 20 on feeder setting table 41, and second cover member 50 as a guide member provided on the mounting machine main body. Further, first cover member 45 is disposed above feeder setting table 41 in component supply unit 40, and second cover member 50 is located above feeder setting table 41 in a state where component supply unit 40 is attached to mounting machine main body 10a and second cover member 50 is positioned at advanced position P1. If component supply unit 40 is removed from mounting machine main body 10a, first cover member 45 is no longer an obstacle for maintenance. Therefore, it is easier to execute maintenance of mounting machine main body 10a.

In addition, in component mounting machine 10, upper end surface 45a of first cover member 45 is positioned at a higher position than suction nozzle 13 held by head 12 when component supply unit 40 is attached to mounting machine main body 10a, and upper end surface 24a of second cover member 50 is positioned at a lower position than suction nozzle 13 held by head 12. In this case, if first cover member 45 is provided on mounting machine main body 10a, head 12 and first cover member 45 are likely to interfere. Therefore, it is highly significant that first cover member 45 is provided in component supply unit 40.

In addition, in component mounting machine 10, second cover member 50 includes detected piece 72 of the detection sensor that detects misalignment of feeder 20 on feeder setting table 41 of component supply unit 40. Further, flap member 71 that rotates relative to the member main body is attached to second cover member 50 when feeder 20 that is connected to second cover member 50 through a rotating shaft that intersects with the setting direction of feeder 20 and that is misaligned comes into contact therewith. Flap member 71 includes detected piece 72, and the detection sensor has detection section 73 that is immovably fixed to mounting machine main body 10a and is capable of detecting detected piece 72 at advanced position P1. In this way, one detection section 73 can monitor misalignment of feeder 20 and movement of second cover member 50.

It is obvious that the present disclosure is not limited to the embodiment described above, and can be practiced in various aspects as long as the aspects belong to the scope of the present disclosure.

In the embodiment described above, an optical sensor is used as detection section 73. However, a non-contact type proximity sensor (an inductive type proximity sensor, a capacitance type proximity sensor, a magnetic proximity sensor, and the like) may be employed as detection section 73, or a contact type limit switch may be used. The non-contact type is more advantageous in terms of durability.

In the embodiment described above, detection sensor 70 is provided on the left and right sides of the area where feeder setting table 41 is disposed. However, detection sensor 70 may be provided on either the left side or the right side of the area where feeder setting table 41 is disposed.

In the embodiment described above, slider lock 60 is provided in front of slider 51 on the left side and slider 51 on the right side of the area where feeder setting table 41 is disposed. However, slider lock 60 may be provided in front of either left slider 51 or right slider 51 in the area where feeder setting table 41 is disposed.

In the embodiment described above, the present disclosure has been described as component mounting machine 10, but may also be applied as a maintenance method for a component mounting machine.

### Industrial Applicability

The present disclosure can be used for a manufacturing industry of component mounting machines, and the like.

### Reference Signs List

1 component mounter, 10 component mounting machine, 10a mounting machine main body, 10b base, 11 board conveyance device, 12 head, 13 suction nozzle, 14 lifting and lowering device, 17 head moving device, 18 Y-axis slider, 19 X-axis slider, 20 feeder, 21 reel holding unit, 22 feeder main body, 23 frame member, 24 rail, 24a upper end surface, 25 positioning pin, 26 connector, 27 tape feeding mechanism, 28 stepped surface, 29 stepped surface, 30 reel, 31 tape, 40 component supply unit, 41 feeder setting table, 42 slot, 43 positioning hole, 44 connector, 45 first cover member, 45a upper end surface, 50 second cover member, 50a upper end surface, 51 slider, 52 guide rail, 53 frame member, 55 notch, 60 slider lock, 61 lock main body, 62 hook, 63 lever, 64 shaft, 65 spring, 66 lock attachment member, 70 detection sensor, 71 flap member, 72 detected piece, 73 detection section, 74 hinge, 75 detection section attachment member, 90 control device, 91 CPU, 92 ROM, 93 storage, 94 RAM, P1 advanced position, P2 retracted position, S board

1. A component mounting machine comprising:
a board conveyance device configured to convey a board;
a mounting machine main body that includes a head configured to hold a collection member and a head moving device configured to move the head, and that is configured to move the head with the head moving device, collect a component supplied from a feeder set on a feeder table, and mount the component on a board conveyed by the board conveyance device; and
a guide member that is provided in the mounting machine main body, and that is configured to move between an advanced position advanced to a feeder table side and a retracted position retracted to a board conveyance device side to guide setting of the feeder on the feeder table in a state of being positioned at the advanced position.

2. The component mounting machine according to claim 1, further comprising:
a component supply unit having the feeder table and detachably attached to the mounting machine main body;
a first guide member that is provided in the component supply unit and that is configured to guide setting of the feeder on the feeder table; and
a second guide member as the guide member provided in the mounting machine main body, wherein
the first guide member is disposed above the feeder table in the component supply unit, and
the second guide member is positioned above the feeder table in a state in which the component supply unit is attached to the mounting machine main body and the second guide member is positioned at the advanced position.

3. The component mounting machine according to claim 2, wherein
an upper end portion of the first guide member is positioned at a higher position than the collection member held by the head in a state in which the component supply unit is attached to the mounting machine main body, and
an upper end portion of the second guide member is positioned at a lower position than the collection member held by the head.

4. The component mounting machine according to claim 2, wherein the second guide member includes a detected piece of a detection sensor configured to detect misalignment of the feeder on the feeder table of the component supply unit.

5. The component mounting machine according to claim 4, wherein
the second guide member includes a member main body, and a rotating body configured to rotate relative to the member main body when the feeder that is connected to the member main body through a rotating shaft that intersects with a setting direction of the feeder and is misaligned comes into contact therewith,
the rotating body includes the detected piece, and
the detection sensor is immovably fixed to the mounting machine main body and includes a detection section capable of detecting the detected piece at the advanced position.

6. A maintenance method of a component mounting machine including a board conveyance device configured to convey a board, a mounting machine main body that includes a head configured to hold a collection member and a head moving device configured to move the head, and that is configured to move the head with the head moving device, collect a component supplied from a feeder set on a feeder table, and mount the component on a board conveyed by the board conveyance device, and a guide member that is provided in the mounting machine main body, and that is configured to move between an advanced position advanced to the feeder table side and a retracted position retracted to the board conveyance device side to guide setting of the feeder on the feeder table in a state of being positioned at the advanced position, the maintenance method comprising:
positioning the guide member at the retracted position; and
performing maintenance on the mounting machine main body.
